(19) United States
(12) Patent Application Publication
(10) Pub. No.: US 2015/0002984 A1
(43) Pub. Date: Jan. 1, 2015

(54) METHOD OF FORMING A MAGNETIC MEMS TUNABLE CAPACITOR

(71) Applicants: Weng Hong TEH, Phoenix, AZ (US); Qing Ma, Saratoga, CA (US); Johanna M. Swan, Scottsdale, AZ (US); Valluri R. Rao, Saratoga, CA (US)

(72) Inventors: Weng Hong TEH, Phoenix, AZ (US); Qing Ma, Saratoga, CA (US); Johanna M. Swan, Scottsdale, AZ (US); Valluri R. Rao, Saratoga, CA (US)

(21) Appl. No.: 13/931,632

(22) Filed: Jun. 28, 2013

(51) Int. Cl. H01L 25/16; H01G 7/00; H01L 43/02; H01L 49/02; H01L 43/12

(52) U.S. Cl. CPC H01L 25/16; H01L 28/40; H01L 43/12; H01L 43/02; H01G 7/00
USPC 361/277; 257/427; 438/3

(57) ABSTRACT

An apparatus including a die; a carrier coupled to the die; and at least one capacitor positioned in or on the carrier, the at least one capacitor including a first electrode, a second electrode and a dielectric material; and a magnet positioned such that a magnetic field at least partially actuates the second electrode toward the first electrode. A method including disposing a die, a first electrode of a capacitor and a magnet on a sacrificial substrate; forming a dielectric layer on the first electrode; patterning a conductive material coupled to the first electrode; patterning a second electrode on the dielectric layer; and removing the sacrificial substrate. A method including exposing a suspended first electrode of a capacitor in a package to a magnetic field; driving a current in a first direction through the first electrode; and establishing a voltage difference between the first electrode and a second electrode.

### BACKGROUND

1. Field

Capacitors and packaging for microelectronic devices.

2. Description of Related Art

Tunable radio frequency (RF) circuits for filters, matching networks RF front end modules (FEMs) and antennas are actively being explored. One solution is the use of tunable capacitors. However, where semiconductor elements are used in RF circuits, insertion loss tends to be too large. Mircoelectromechanical systems (MEMs) tunable capacitors have been explored for RF circuit applications. Typically, such tunable capacitors using electrostatic actuation suffer from either operation issues, generally requiring a high actuation voltage and/or reliability issues, generally associated with dielectric charging related stiction.

### BRIEF DESCRIPTION OF THE DRAWINGS

FIG. 1 is a plan view schematic of a capacitor assembly.

FIG. 2 shows a side view of the capacitor assembly of FIG. 1 in an “off” state.

FIG. 3 shows a side view of the capacitor assembly of FIG. 1 following the application of a force on the suspended electrode to actuate the electrode toward the other electrode.

FIG. 4 shows a side view of the capacitor assembly of FIG. 1 and full contact between the suspended electrode and the other electrode.

FIG. 5 shows a plan view schematic of another embodiment of a capacitor assembly.

FIG. 6 shows a plan view schematic of another embodiment of a capacitor assembly.

FIG. 7 shows a plan view schematic of another embodiment of a capacitor assembly.

FIG. 8 shows a plan view schematic of another embodiment of a capacitor assembly.

FIG. 9 shows a plan view schematic of another embodiment of a capacitor assembly.

FIG. 10 shows a cross-sectional exploded side view of sacrificial substrate with sacrificial foils on opposite sides thereof.

FIG. 11 shows the structure of FIG. 10 following the attachment of a die and a substrate on the sacrificial foils and the introduction of a base electrode on the substrate and a dielectric layer on the base electrode.

FIG. 12 shows a plan view of the structure of FIG. 11 and illustrates magnets on the substrate on opposite sides of the base electrode.

FIG. 13 shows the structure of FIG. 11 following the introduction of a dielectric film on the die and substrate.

FIG. 14 shows the structure of FIG. 13 following the introduction of conductive vias to the die and the base electrode and a conductive line or level and the suspended electrode.

FIG. 15 shows the structure of FIG. 14 following the introduction and patterning of a sacrificial material on the structure exposing the suspended electrode.

FIG. 16 shows the structure of FIG. 15 following the removal of dielectric material between the suspended electrode and the dielectric layer on the base electrode.

FIG. 17 shows a plan view of the structure of FIG. 16.

FIG. 18 shows the structure of FIG. 16 following the introduction of additional build-up layer.

FIG. 19 shows the structure of FIG. 18 following the separation of the structure from the sacrificial substrate and foils and connection to a printed circuit board as an assembly in a computing device.

FIG. 20 illustrates a computing device in accordance with one implementation.

### DETAILED DESCRIPTION

Described herein are embodiments of digital and analog tunable thin film capacitors amenable to fabrication in packaging. Representatively, such capacitors are contained in a package that acts as an interface and allows a connection to another device or assembly, such as printed circuit board. Bumpless Build-Up Layer (BBUL) technology is one approach to a packaging architecture. Among its advantages, BBUL eliminates the need for assembly, eliminates prior solder ball interconnections (e.g., flip-chip interconnections), reduces stress on low-k interlayer dielectric of dies due to die-to-substrate coefficient of thermal expansion (CTE) mismatch, and reduces package inductions through elimination of core and flip-chip interconnect for improved input/output (I/O) and power delivery performance.

Typical of BBUL technology is a die or dies embedded in a substrate such as bismaleimide triazine (BT) laminate or a copper heat spreader, which then has one or more build-up layers formed thereon. A process such as laser drilling and plating may be used for via formation to contacts on the die or dice. Build-up layers of, for example, alternating layers of patterned conductive material and insulating material are applied as films. In one embodiment, such pattern conductive layers may include other devices or portions of devices such as patterned electrodes for a capacitor or capacitors. Capacitors typically include a pair of electrodes or plates with a dielectric layer disposed there between. In one embodiment, to form a dielectric layer between the electrodes of a capacitor, thin film deposition techniques, such as plasma-enhanced CVD are employed.

As noted above, tunable capacitors are typically actuated by electrostatic actuation. Such actuation can lead to stiction. In one embodiment, the capacitors described herein are actuated at least in part using magnetic actuations that allows a reduced voltage and avoids charging induced stiction.

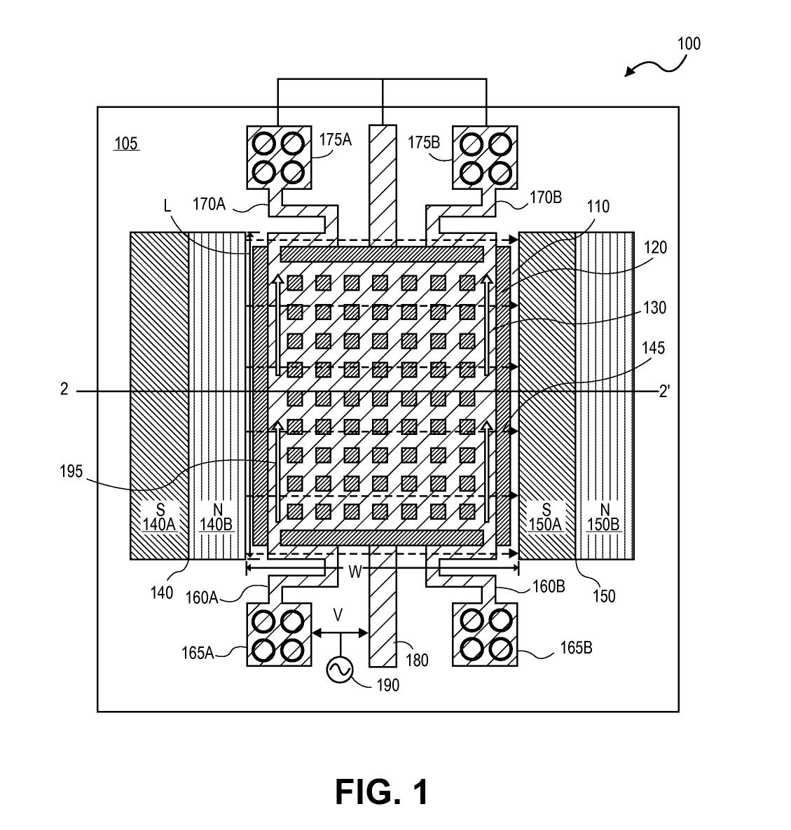

FIG. 1 is a plan view schematic of a capacitor assembly. Capacitor assembly 100, in one embodiment, is formed in or on a carrier or package, such as a build-up package. In one embodiment, capacitor assembly 100 is disposed on substrate 105. Substrate 105 may be any material utilized in the art of MEMs or microelectronics packaging, such as, but not limited to silicon, glass, epoxy, metals, dielectric films, organic films, etc. Capacitor 100 includes electrode 110 disposed on substrate 105. In one embodiment, electrode is a conductive material such as copper or copper alloy deposited by electrolytic or electroless plating on substrate 105 and patterned using etching techniques (e.g., flash etching) and/or semi-additive processes (typical of substrate packaging processing) into desired dimensions for electrode 110. Electrode 110 is substantially planar with a plane parallel to a plane defined by a surface of substrate 105.

A representative thickness of electrode 110 can range from 10 μm-30 μm if based upon conventional substrate semi-additive processes (e.g., dry film resist (DFR)) patterning, electroless seed plating, electrolytic plating, DFR removal and flash seed etching) similar to conductive layer thicknesses in build-up processes. If thinner layers are desired, this can be done using sputtering technology representatively by moving toward more semiconductor fabrication deposition techniques for substrate processing. A length and width of electrode 110 will depend, in one embodiment, on a design and also an effective area of a needed “active capacitance.” Representative sizes can range from 20 μm×20 μm up to 500 μm×500 μm.

On a surface of electrode 110 is dielectric layer 120. In one embodiment, dielectric layer 120 is a dielectric material that is deposited by a thin film deposition technique, such as by CVD or PECVD. Suitable materials include, but are not limited to, silicon nitride (SiN) or silicon oxynitride (SiON), silicon carbide (SiC), SiCN. A representative thickness of dielectric layer 120 of SiN is on the order of 50 μm to 300 μm. In one embodiment, a thickness depends on the desired capacitance(s) and its control and also on the deposition technique used (e.g., PECVD, LPCVD, ALD).

Suspended over electrode 110 and dielectric layer 120 is electrode 130. In one embodiment, electrode 130 is a conductive material such as copper or a copper alloy introduced onto substrate 105 by plating and patterning to have a length, L, and width, W. In one embodiment, electrode 130 is suspended over electrode 110 and dielectric layer 120 by a gap and supported by suspension springs 160A, 160B, 170A and 170B. Suspension springs 160A and 160B are connected to electrode 130 at one side. Suspension springs 170A and 170B are connected to electrode 130 at opposite sides (opposing sides defined by width, W). Suspension springs 160A, 160B, 170A and 170B are, for example, a conductive material such as copper or a copper alloy formed through plating and, in one embodiment, are symmetrical in the sense that each spring has similar spring constant. Suspension springs 160A, 160B, 170A and 170B are also connected to anchors 165A, 165B, 175A and 175B, respectively. Anchors 165A, 165B, 175A and 175B are connected to substrate 105 and are a conductive material such as copper or a copper alloy.

Disposed below electrode 110 (as viewed), in one embodiment, is ground strip 180. In one embodiment, ground strip 180 is, for example, a conductive material such as copper or a copper alloy introduced by a plating process.

In one embodiment, disposed adjacent to opposite lateral sides of electrode 110 and electrode 130 (along a length dimension, L) are magnet 140 and magnet 150. In this embodiment, magnet 140 has south pole 140A and north pole 140B. Magnet 150 has south pole 150A and north pole 150B. Magnet 140 and magnet 150 are arranged such that opposite poles are positioned on opposite sides of electrode 130. As indicated, a magnetic field, indicated by arrow 145, is directed across the electrodes in a width direction, W, from north pole 140B of magnet 140 towards south pole 150A of magnet 150. In one embodiment, each of magnet 140 and magnet 150 are having a thickness on the order of 200 μm.

As shown in FIG. 1, capacitor 100 is connected to voltage source 190. Voltage source 190 is present on substrate 105 and is connected to anchor 165A and ground bar 180. Voltage source 190 is configured to supply a current (represented by arrow 195) through suspension spring 160A. The current is configured to extend through electrode 130 in a length direction, L, toward opposing spring 170A. Without wishing to be bound by theory, a current, in combination with the magnetic field extending in a generally orthogonal direction relative to the current flow, a Lorentz Force is produced on electrode 130 having a vector in the direction to actuate or move electrode 130 toward electrode 110.

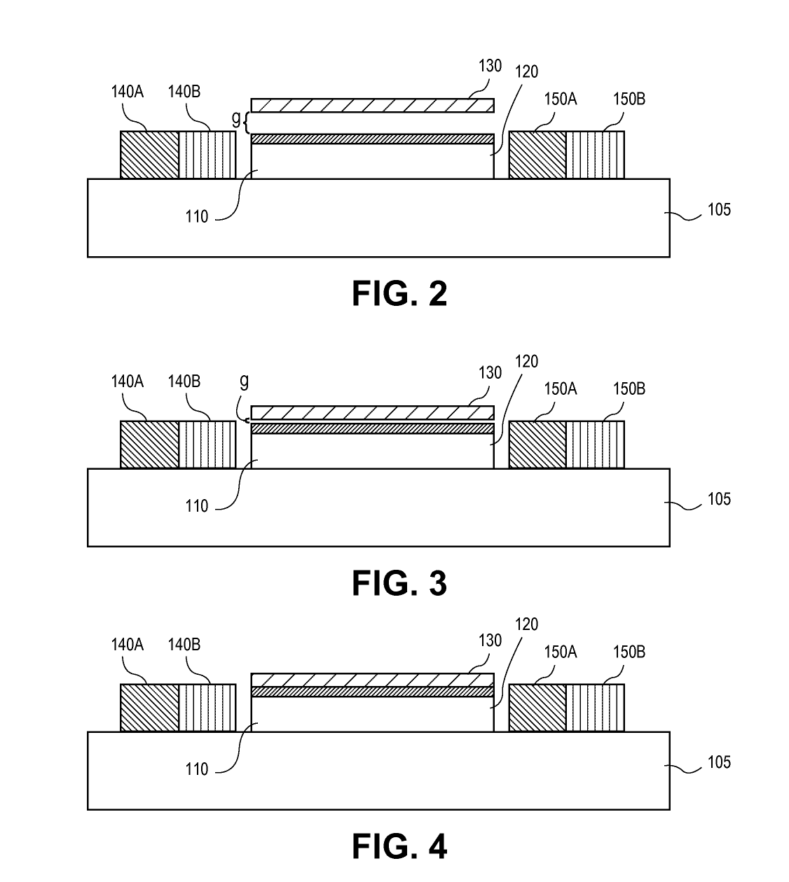

In one embodiment (a digital mode), a voltage difference between electrode 110 and electrode 130 is established to establish full contact between electrode 130 and dielectric layer 120. FIGS. 2-4 illustrate the actuation of electrode 130. Referring to FIG. 2, in this configuration, capacitor 100 is in the “off” mode and C_{off} is small (e.g., with a gap of 20 μm and an effective area of 6E-8 m2, “off” mode is less than 0.16 picoFarads (pF), i.e., very much isolated with negligible leakage). Electrode 130 is illustrated as suspended over dielectric layer 120 by gap, g.

FIG. 3 shows capacitor 100 in the “on” mode with Lorentz force 210 applied to electrode 130 through the application of magnetic field 145 and current 195. The Lorentz force reduces gap, g, between electrode 130 and electrode 110. FIG. 4 shows capacitor 100 following the application of a voltage between electrode 130 and electrode 110 (a voltage difference) to close the gap (g=0). An example is electrode 110 and electrode 130 having length and width dimensions of 300 μm×300 μm with dielectric layer 120 of a SiN having a thickness from 50 μm-200 μm giving “on” capacitances from 16-74 pF.

The above embodiment described capacitor 100 operating in a digital mode (e.g., capacitor 100 either “on” or “off”). In another embodiment, capacitor 100 may be operated in an analog mode. In an analog mode, a voltage, V, from voltage source 190 is tuned so that a contact area between electrode 130 and dielectric layer 120 may be adjusted to provide a range of capacitance. One way an analog mode may be implemented is by including a feedback loop.

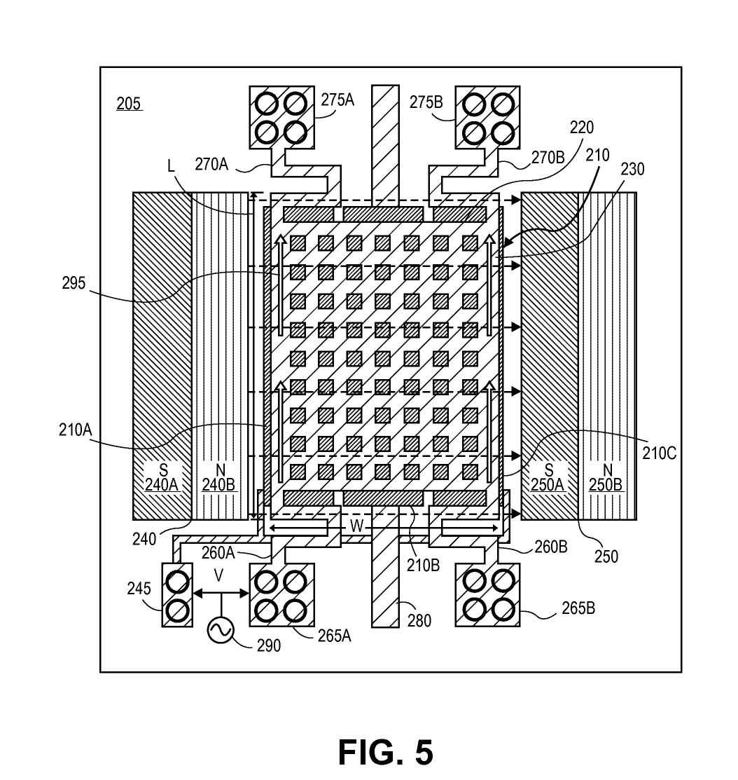

FIG. 5 shows a plan view schematic of another embodiment of a capacitor assembly. Capacitor assembly 200 is formed in or on a package, such as a build-up package. In one embodiment, capacitor assembly 200 is disposed on substrate 205 that may be any material utilized in the art of MEMs or microelectronics packaging. Capacitor assembly 200 includes electrode 210 disposed on substrate 205. In this embodiment, electrode 210 of, for example, a conductive material such as copper or a copper alloy is divided into multiple sections (e.g., two or more sections). FIG. 5 shows electrode 210 including section 210A, section 210B and section 210C. Each electrode section is separated from an adjacent section along a width dimension, w, of electrode 210.

On a surface of each of electrode section 210A, electrode section 210B and electrode section 210C is a dielectric material layer. In one embodiment, dielectric layer 220 is a dielectric material such as SiN, SiON, SiC and SiCN that is deposited by a thin film deposition technique, such as by CVD or PECVD.

Suspended over each electrode section 210A, 210B and 210C and over dielectric layer 220 is electrode 230. In one embodiment, electrode 230 is similar to electrode 130 described with references to FIGS. 1-4. Electrode 230 is suspended a distance over dielectric layer 220 by suspension springs 260A, 260B, 270A and 270B that, in this embodiment, are symmetrical in the sense that each spring has a similar spring constant. In addition to being connected to electrode 230, suspension springs 260A, 260B, 270A and 270B are connected to anchors 265A, 265B, 275A and 275B, respectively, with the anchors connected to substrate 205. Suspension springs 260A, 260B, 270A and 270B may be formed by plating and patterning techniques.

Disposed below electrode 210 (as viewed), in one embodiment, is ground strip 280 of, for example, a conductive material such as copper also formed by plating and patterning techniques.

In one embodiment, disposed adjacent to opposite lateral length sides of electrode 210 and electrode 230 are magnet 240 and magnet 250. Magnet 240 has south pole 240A and north pole 240B. Magnet 250 has south pole 250A and north pole 250B. As indicated, a magnetic field, indicated by arrow 245, is directed across the electrodes in a width direction, w, from north pole 240B of magnet 240 toward south pole 250A of magnet 250.

As shown in FIG. 5, capacitor assembly 200 is connected to voltage source 290. Voltage source 290 is present on substrate 205 and is connected to anchor 265A and ground strip 280. Voltage source is configured to supply a current (represented by arrow 295) through at least suspension spring 260A and through electrode 230 in a length direction, L, toward opposing spring 270A. Without wishing to be bound by theory, in combination with the magnetic field extending in a generally orthogonal direction relative to the current flow, a Lorentz force is produced on electrode 230 having a direction to actuate or move electrode 230 toward electrode 210. In one embodiment (a digital mode), a voltage difference between electrode 210 and electrode 230 is established to establish full contact between electrode 210 and electrode 230.

As noted above, in the embodiment of a capacitor illustrated in FIG. 5, electrode 210 of capacitor 200 is divided into three sections (section 210A, section 210B and section 210C). In one embodiment, to provide a voltage difference between electrode 210 and electrode 230, additional electrode 245 of a conductive material (e.g., copper) is provided on substrate 205 and connected to each section of electrode 210 (section 210A, section 210B and section 210C) through, for example, a line of conductive material (e.g., copper) between additional electrode 245 and the sections of electrode 210.

In addition to a digital mode, capacitor assembly 200 can also be operated in an analog mode. In an analog mode, a voltage from voltage source 290 is tuned so that a contact area between electrode 230 and dielectric layer 220 is modified (e.g., not complete contact) to provide a range of capacitance. A feedback loop may be employed to obtain a desired capacitance.

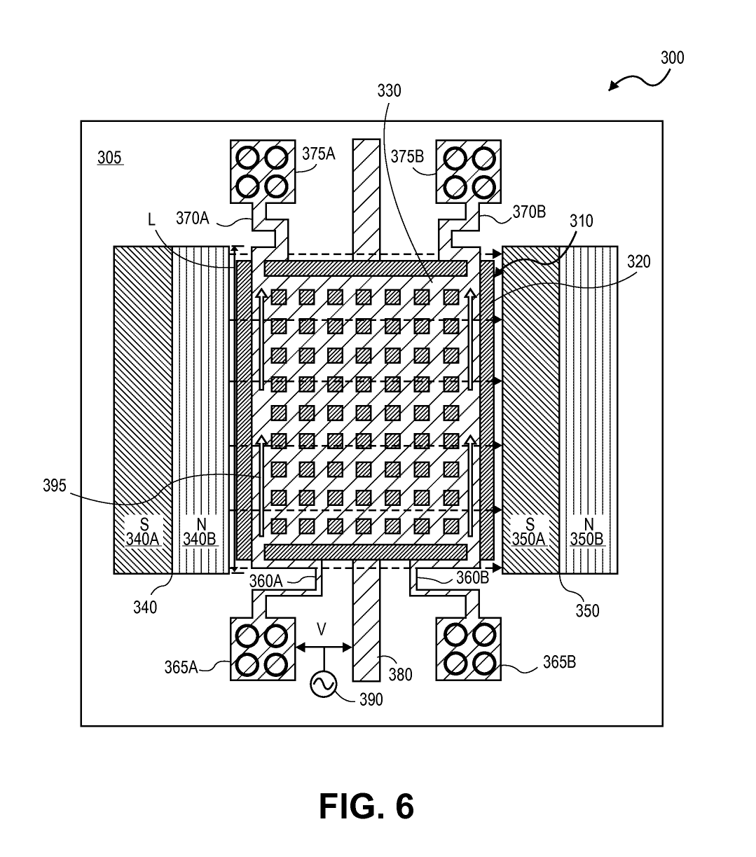

FIG. 6 shows a plan view schematic of another embodiment of a capacitor assembly. Capacitor assembly 300 is similar to capacitor assembly 100 described with reference to FIG. 1 in the sense that it includes electrode 310 of, for example, a conductive material such as copper or a copper alloy disposed on a substrate such as a package; dielectric layer 320 of a material such as SiN, SiON, SiC and SiCN deposited by a thin film deposition technique, such as by CVD or PECVD; electrode 330 suspended over electrode 310 and dielectric layer 320; and magnet 340 (including south pole 340A and north pole 340B) and magnet 350 (including south pole 350A and north pole 350B) disposed adjacent to opposite lateral length sides of electrode 310 and electrode 330. In this embodiment, electrode 330 is suspended over dielectric layer 320 by suspension springs 360A, 360B, 370A and 370B that, in this embodiment, are asymmetrical in the sense that suspension springs 360A and 360B on one side of electrode 330 have a spring constant that is less than a spring constant of suspension springs 370A and 370B on an opposing side. In this manner, the difference in spring constant of the suspension springs is perpendicular to a direction of a magnetic field (e.g., a B field) produced by magnet 340 and magnet 350 to allow a larger capacitance tuning range than with symmetrical springs. In operation, the suspension springs 360A and 360B would tend to collapse before suspension springs 370A and 370B allowing suspension springs 370A and 370B to be tunable across a larger range of possible contacting areas to form the effective capacitance.

Suspension spring 360A, suspension spring 360B, suspension spring 370A and suspension spring 370B are connected to anchor 365A, anchor 365B, anchor 375A and anchor 370B, respectively, with each anchor connected to substrate 305. Voltage source 390 associated with substrate 305 is connected to anchor 365A and ground strip 380. A voltage source is configured to supply a current (represented by arrow 395) in a direction, L, toward opposing spring 370A. In combination with the magnetic field produced by magnets 340 and 350 in a generally orthogonal direction relative to a direction of the current, a Lorentz force is produced on electrode 330 in a direction to actuate or move electrode 330 toward electrode 310. In one embodiment (a digital mode), a voltage difference between electrode 310 and electrode 330 is established to establish full contact between electrode 310 and electrode 330.

In addition to a digital mode, capacitor 300 can also be operated in an analog mode. In an analog mode, a voltage from voltage source 390 is tuned so that a contact area between electrode 330 and dielectric layer 320 is modified (e.g., not complete contact) to provide a range of capacitance. A feedback loop may be employed to obtain a desired capacitance.

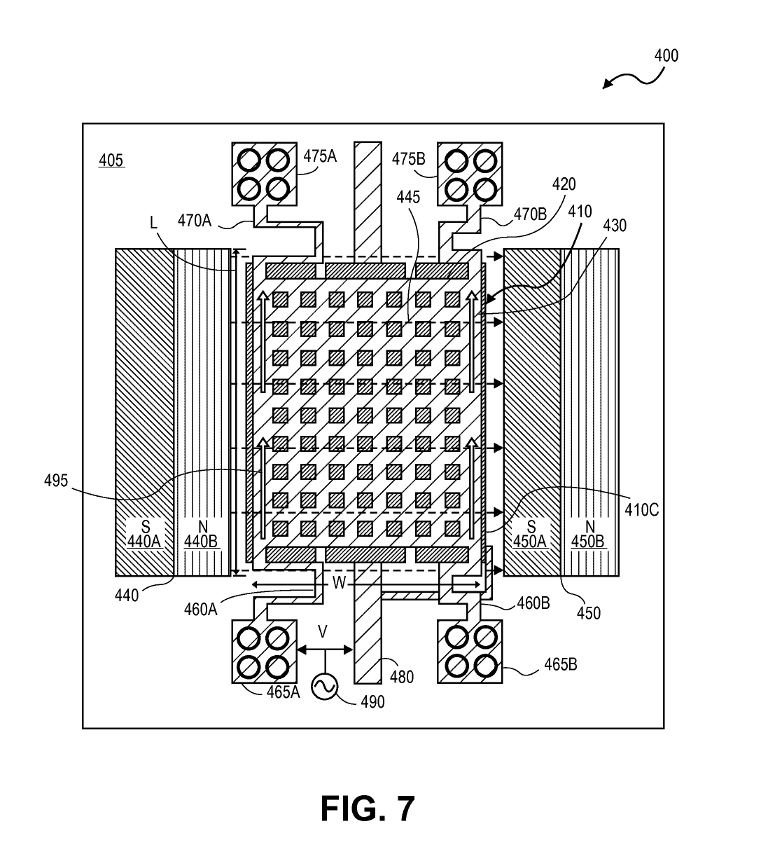

FIG. 7 shows a plan view schematic of another embodiment of a capacitor assembly. Capacitor assembly 400 is similar to capacitor assembly 100 described with reference to FIGS. 1-4 in the sense that capacitor assembly 400 includes electrode 410 disposed on substrate 405 of a package such as a build-up package; dielectric layer 420 of a dielectric material such as SiN, SiON, SiC and SiCN deposited by a thin film deposition technique such as CVD or PECVD; electrode 430 suspended over electrode 410 and dielectric layer 420 by suspension springs 460A, 460B on one side and suspension springs 470A, 470B on an opposing side; and magnet 440 and magnet 450 disposed on opposing lateral length sides of the electrodes. In this embodiment, suspension springs on each side of electrode 430 are asymmetrical with respect to one another in the sense that spring 460A has a smaller spring constant than suspension spring 460B and suspension spring 470A has a smaller spring constant than suspension spring 470B. As viewed, the suspension springs with the smaller spring constant (suspension spring 460A and suspension spring 470A) are disposed on opposing sides of a left side of electrode 430, as viewed, while suspension spring 460B and suspension spring 470B with the greater spring constant are disposed on a right side, as viewed. Disposing the springs with the lower spring constant on the left allows for a collapse of the left hand side of electrode 430 more easily than the right hand side of the electrode. In this manner, the tunability of the capacitor across a larger range of possible contacting areas is possible to form an effective capacitance.

As shown in FIG. 7, capacitor assembly 400 is connected to voltage source 490. Voltage source 490 is present on substrate 405 and is connected to anchor 465A and ground strip 480. Voltage source 490 is configured to supply current (represented by arrow 495) through at least suspension spring 460 and through electrode 430 in a length direction, L, toward opposing spring 470A. In one embodiment, disposed adjacent to opposite lateral length sides of electrode 410 and electrode 430 are magnet 440 and magnet 450. Magnet 440 includes south pole 440A and north pole 440B while magnet 450 includes south pole 450A and north pole 450B. As indicated, a magnetic field, indicated by arrow 445 is directed across the electrode in a width direction, from north pole 440B of magnet 440 toward south pole 450A of magnet 450. Without wishing to be bound by theory, in combination with current 495, the magnetic field produces a Lorentz force on electrode 430 having a direction to actuate or move electrode 430 toward electrode 410. Because suspension spring 460A and suspension spring 470A on a left side of electrode 430 have a spring constant that is less than a spring constant of suspension springs 460B and 470B on a right side of electrode 430 (as viewed), the left side of electrode 430 will be actuated or moved toward dielectric layer 420 before the right side of electrode 430. A voltage between electrode 430 and electrode 410 may then be applied to pull down the entire electrode.

In another embodiment, capacitor assembly 400 includes only magnet 440 on one lateral side of electrode 430. A single magnet such as magnet 440 without reason to be bound by theory, it is believed that the a magnetic field (e.g., a B field) created by magnet between the different poles of magnet 440 in combination with the current will produce a sufficient force to actuate electrode 430 toward electrode 410, particularly the left side of electrode 430 that is suspended by suspension spring having a smaller spring constant relative to the right side of electrode 430.

In addition to a digital mode, capacitor assembly 400 can also be operated in an analog mode. In an analog mode, a voltage from voltage source 490 is tuned so that a contact area between electrode 430 and dielectric layer 420 is modified to provide a range of capacitance. A feedback loop may be employed to obtain a desired capacitance.

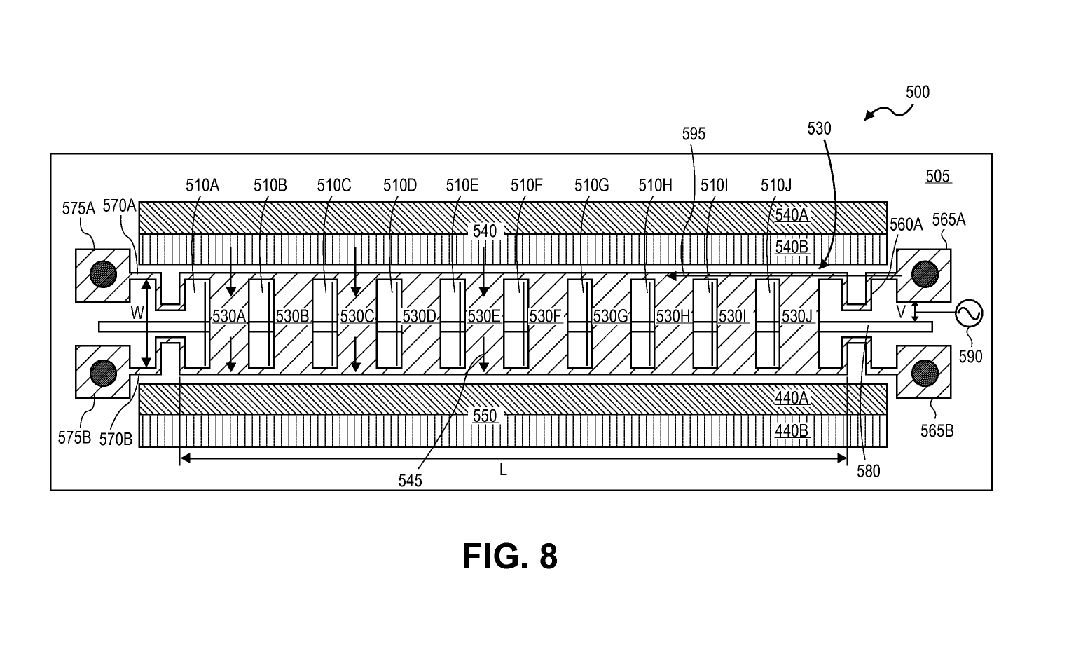

FIG. 8 shows a plan view schematic of another embodiment of a capacitor assembly in or on a package. In this embodiment, capacitor assembly is disposed on substrate 505 and is made up of a number of capacitors disposed in parallel with respect to one another. From left to right, capacitor assembly 500 includes electrode 510A, electrode 510B, electrode 510C, electrode 510D, electrode 510E, electrode 510F, electrode 510G, electrode 510H, electrode 510I and electrode 510J patterned of, for example, a conductive material such as copper or copper alloy. The electrodes may be introduced onto substrate 505 (e.g., a package substrate) as a sheet and patterned into individual electrode. Overlying each electrode (electrodes 510A-510J) is a layer of dielectric material such as SiN, SiON, SiC and SiCN deposited by think film deposition technique such as by CVD or PECVD. Suspended over the dielectric layer on each of electrodes 510A-510J is electrode assembly 530. Electrode assembly includes a number of individual electrodes having dimension similar to and aligned over the base electrodes (electrodes 510A-510J). FIG. 8 illustrates electrode 530A, electrode 530B, electrode 530C, electrode 530D, electrode 530E, electrode 530F, electrode 530G, electrode 530H, electrode 530I and electrode 530J disposed over the respective ones of the base electrodes (electrodes 510A-510J). Electrode assembly 530 is suspended over the dielectric layer of base electrode by suspension springs (suspension spring 560A, suspension spring 560B, suspension spring 570A and suspension spring 570B). In one embodiment, the suspension springs are symmetric in the sense that each a similar spring constant. Suspension springs 560A-560B and 570A-570B are connected to substrate 105 through respective anchors 565A, 565B, 575A and 575B. In one embodiment, electrode assembly 530 is formed by introducing a sheet or film of a conductive material such as copper or copper alloy by, for example, plating techniques and patterning such sheet of film into the individual electrode components and patterning the suspension springs. FIG. 8 also shows magnet 540 and magnet 550 disposed on opposite lateral sides of electrode assembly 530. Magnet 540 includes south pole 540A and north pole 540B. Magnet 550 includes south pole 550A and north pole 550B. The magnetic field, indicated by arrow 545, is directed across the electrode being with direction, W, from north pole 540B of magnet 540 toward south pole 550A of magnet 550. Capacitor assembly 500 is connected to voltage source 590 present on substrate 505. Voltage source 590 is connected to anchor 565A and is configured to supply current (represented by arrow 595) through at least suspension spring 560A and through electrode assembly 530 in a length direction, L, toward opposing spring 570A. In combination with an orthogonally directed magnetic field, a force is produced to actuate or move each of the electrodes of electrode assembly 530 toward corresponding base electrodes (electrodes 510A-510J). Each electrode of electrode assembly 530, when in contact with each respective base electrode, as a capacitance, c. Each base electrode can be independently controlled by establishing a voltage difference between voltage source 590 and the electrode. Accordingly, initially the combination of the current and the magnetic field actuate each electrode of electrode assembly 530 for its base electrode and the voltage difference between voltage source 590 and each base electrode maintains the connection. Depending on the capacitance needed, only certain electrodes (e.g., M electrodes) of electrode assembly 530 are held down to give an overall capacitance of C=MC. As the situation changes, the number of plates held down can be varied.

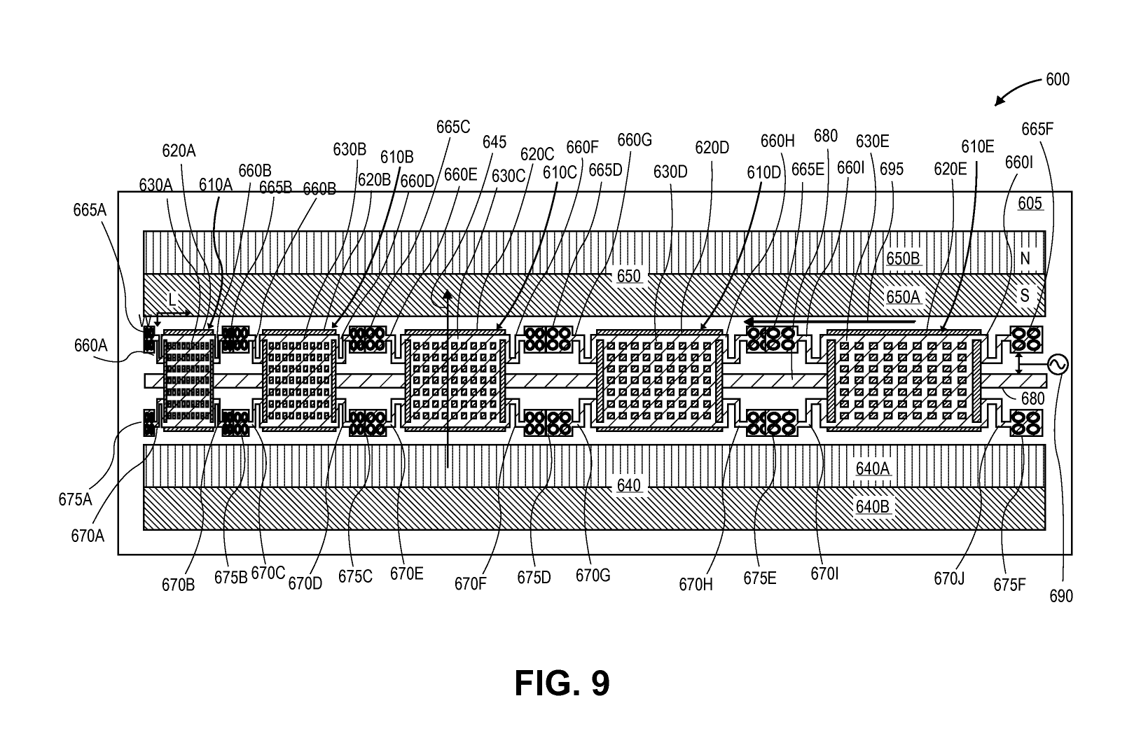

FIG. 9 shows a plan view schematic of another embodiment of a capacitor assembly formed on a substrate, such as a package substrate. Capacitor assembly 600 is similar to capacitor assembly 500 in the sense that it includes base electrodes (base electrode 610A, base electrode 610B, base electrode 610C, base electrode 610D, and base electrode 610E) on substrate 605 (e.g., patterned from a film of conductive material); overlying each base electrode is SiN, SiON, SiC and SiCN deposited by thin film deposition technique; and suspended electrode (electrode 630A, electrode 630B, electrode 630C, electrode 630D and electrode 630E) over respective one of the base electrodes. In this embodiment, the various capacitors are connected in parallel and the electrodes of the respective ones of the capacitors have different areas. Thus, in one embodiment, suspended electrode 630A and corresponding base electrode 610A each has an area (length dimension×width dimension) that is less than an area of suspended electrode 630B and less than an area than the capacitor defined by suspended electrode 630B and base electrode 610B. In the embodiment illustrated in FIG. 9, the area of the electrode in each capacitor assembly is reduced from right to left so that capacitor defined by suspended electrode 630E and base electrode 610E is the largest capacitor.

Each of the individual capacitor of capacitor assembly 600 is connected on opposing side to suspension springs. FIG. 9 shows suspended electrode 630A connected to suspension springs 660A and 670A on one side and suspension springs 660B and 670B on an opposite side defining a width dimension. Suspension spring 660A is connected to substrate 605 through anchor 665A; suspension spring 670A through anchor 675A; suspension spring 660B through anchor 665B; and suspension spring 670B through anchor 675B. The capacitor defined by suspended electrode 630B is connected to suspension spring 660C and 670C on one side and suspension spring 660D and 670D on opposite sides. Since suspension spring 660C is connected to anchor 665B; suspension spring 670C to anchor 675B; suspension spring 660D to anchor 665C; and suspension spring 670D to anchor 675D. Suspended electrode 630C is connected to suspension spring 660E and suspension spring 670E on one side and suspension spring 660F and suspension spring 670F on an opposite side. Suspension spring 660E is connected to anchor 665C; suspension spring 670E is connected to anchor 675C; suspension spring 660F to anchor 665D; and suspension spring 670F to anchor 675D. Suspended electrode 630D is connected to suspension spring 660G and suspension spring 670G on one side and suspension spring 660H and suspension spring 670H on an opposite side. Suspension spring 660G is connected to anchor 665D; suspension spring 670G is connected to anchor 675D; suspension spring 660H to anchor 665E; and suspension spring 670H to anchor 675E. Suspended electrode 630D is connected to suspension spring 660I and suspension spring 670I on one side and suspension spring 660J and suspension spring 670J on an opposing side. Suspension spring 660I is connected to anchor 665E; suspension spring 670I is connected to anchor 675E; suspension spring 660J to anchor 665F; and suspension spring 670J to anchor 675F.

A voltage source is connected to capacitor assembly 600. FIG. 9 shows voltage source 690 connected to anchor 665F. Voltage source 690 is configured to deliver a current, illustrated by arrow 695, through suspension spring 660J and through each of the suspended electrodes in a length direction. In addition, magnet 650 (including south pole 650A and north pole 650B) and magnet 640 (including north pole 640A and south pole 640B) are disposed on opposite lateral sides of the individual capacitors. A magnetic field, indicated by arrow 645, is directed across the electrodes in a width direction, W, from north pole 640A toward south pole 650A. In combination with current 695, the suspended electrodes may be actuated or moved toward the base electrodes. In one embodiment, a voltage difference between the base electrodes and the suspended electrodes is established full contact between the base electrode and the suspended electrode.

The capacitor assembly illustrated in FIG. 9 may be configured in several ways. In one embodiment, where each of the suspension springs that suspend each electrode has the same spring constant but, as illustrated, the areas of the respective electrodes is different, currents (e.g., on the order of 100 milliamps (mA) tend to actuate all the suspended electrodes toward their respective base electrodes. A smaller current will tend not to actuate the smallest suspended electrode toward the base electrode because it is under the smaller force. Incrementally, smaller currents will actuate a smaller number of suspended electrodes toward the respective base electrodes.

Instead of changing the actuation current, a holding voltage may be modified. In an embodiment where the suspension springs that suspend the various suspended electrodes have similar spring constants but as illustrated, the electrodes have different areas. A larger voltage (e.g., larger in the millivolt range) will tend to hold all the suspended electrodes in contact with the dielectric layer on the respective bottom electrodes. Incrementally, smaller voltages will hold fewer suspended electrodes down.

In another embodiment, rather than having the suspension spring suspending each of the suspended electrodes be the same spring constant, the spring constants may be different. In one instance, large currents will tend to actuate all the suspended electrodes toward a base electrode, while smaller currents will tend not to actuate the electrodes having the larger spring constant. Incrementally, smaller currents will actuate a smaller number of electrodes.

In still another embodiment, where the suspension springs for individual suspended electrodes of individual capacitors are different, a holding voltage may be changed. In one embodiment, the holding voltage is sufficient to pull all electrodes to hold all suspended electrodes in contact with bottom electrodes. Alternatively, incrementally smaller voltages will hold a smaller number of suspended electrodes down.

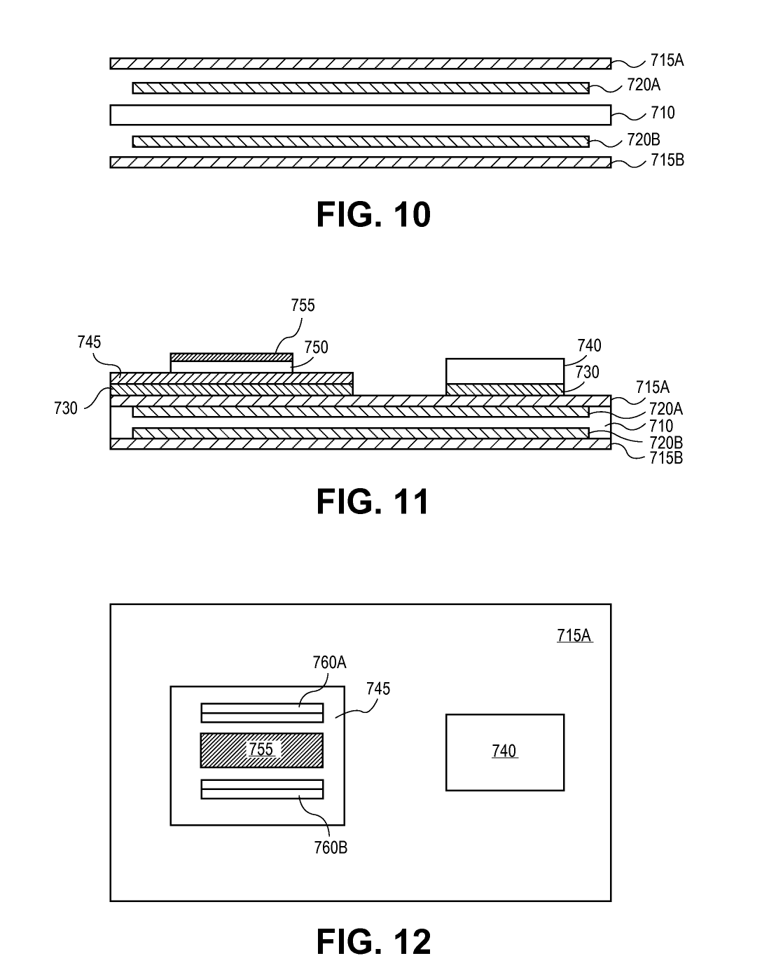

FIGS. 10-19 describe one embodiment of a method for forming a microelectronic package 100 (FIG. 1) including one or more capacitor assemblies embedded therein. The method will describe the incorporation of a single capacitor assembly. The techniques described can be used, however, to incorporate a number of capacitor assemblies in or on a package. The method will also describe the incorporation of a capacitor assembly in a build-up package, on a first level of the package. As will be clear from the description of forming build-up packages, the method described can be used to form one or more capacitors on another level or levels of the package. Further, the capacitor assemblies described herein are not limited to implementation in or on a build-up package.

Referring to FIG. 10, FIG. 10 shows an exploded cross-sectional side view of a portion of a sacrificial substrate 710 of, for example, a prepeg material including opposing layers of copper foils 715A and 715B that are separated from sacrificial substrate 710 by shorter copper foil layers 720A and 720B, respectively. One technique in forming package assemblies using build-up technology is to form package assemblies on opposite sides of sacrificial substrate 710. This discussion will focus on the formation of a package assembly on one side of sacrificial substrate 710 (the “A” side). It is appreciated that a second package assembly can simultaneously be formed on the opposite side (the “B” side).

FIG. 11 shows the structure of FIG. 10 following the mounting of die 740 on the structure. Die 740 is mounted on copper foil 715A through adhesive 730 such as die back side film (DBF) polymer/epoxy based adhesive with or without fillers. Die 740 is mounted with its device side away from the copper foil.

FIG. 11 also shows the structure of FIG. 10 following the introduction of optional substrate 745 of the structure. In this embodiment, substrate 745 will serve as a platform for a capacitor assembly. Substrate 745 on, for example, a silicon material is mounted on copper 715A through adhesive 730 (e.g., DBF). A thickness of substrate 745 is selected, in one aspect, in view of a desire to pattern a suspended electrode in a first level of conductive material along with other structures (e.g., traces). In another embodiment, a thickness of substrate 745 is similar to a thickness of die 740 (e.g., 50 μm to 400 μm).

Disposed on substrate 745 is electrode 750. Electrode 750 is, for example, a conductive material such as copper or a copper alloy. In one embodiment, an electrode is formed of a conductive material such as copper, by way of a semi-additive process including electroless seed plating, DFR patterning/electrolytic plating followed by flash etching to form the electrode. Representative dimensions for electrode 750 in a capacitor assembly such as capacitor assembly 100 (FIGS. 1-4) are on the order of 100 μm×100 μm to 500 μm×500 μm. Overlying electrode 750, in this embodiment, is dielectric layer 755. Dielectric layer 755 is, for example, SiN, SiON, SiC and SiCN introduced by a thin film deposition technique such as CVD or PECVD.

Also disposed on substrate 745 is a pair of magnets. Although not visible in the cross-section of FIG. 11, FIG. 12 shows a top plan view of the structure of FIG. 11. As illustrated in FIG. 12, magnet 760A and magnet 760B are disposed on substrate 745 and opposite sides of electrode 750. In one embodiment, each magnet is a about 200 μm thick.

Contacts for connecting a microelectronic package to another package (a POP configuration) or a device may also be introduced on copper foil 715A. Such contacts 725A and 725B may be formed by deposition (e.g., plating, sputter deposition, etc.) and patterning at a desired location for possible electrical contact with another package or device.

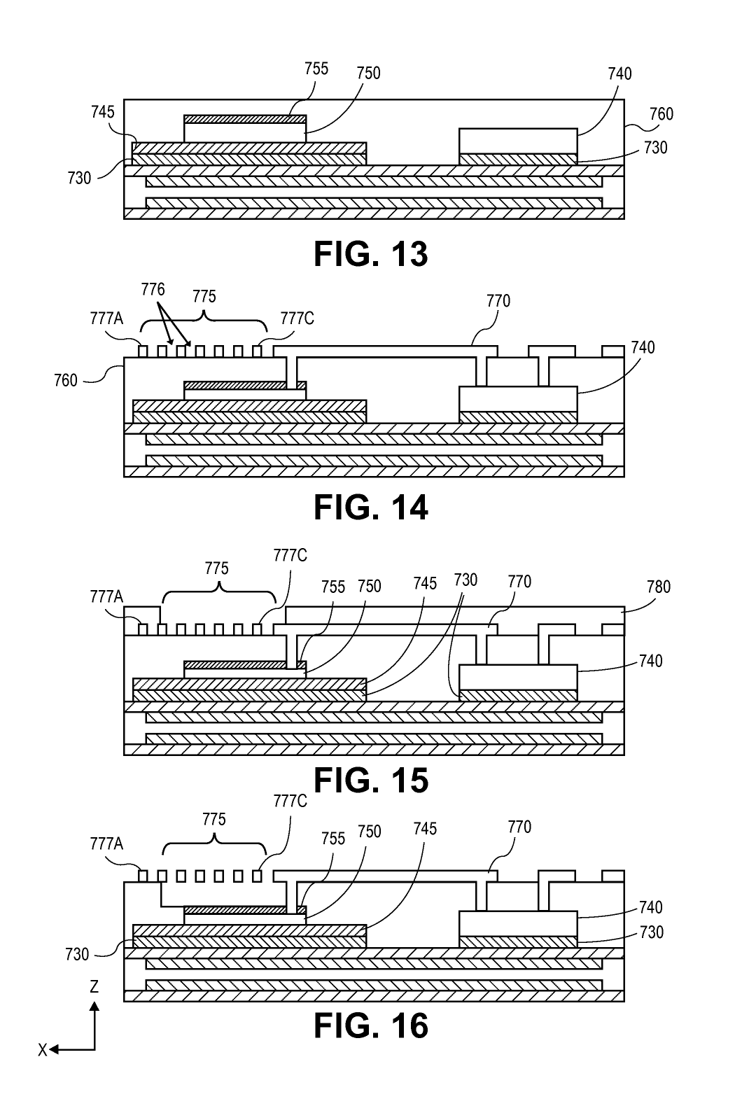

Following the mounting of die 740 and the introduction of electrode 750, dielectric layer 755 and magnets 760A and 760B on copper foil 715A, a dielectric material is introduced to encapsulate the die and the electrode/dielectric layer. One suitable dielectric material is an ABF material introduced, for example, as a film or films (a laminate or laminates). FIG. 13 shows dielectric material 760 encapsulating die 740 and electrode 750/dielectric layer 755. In one embodiment, a thickness of dielectric material 760 on dielectric layer 755 determines a gap between electrodes of a capacitor assembly.

FIG. 14 shows conductors formed in vias through dielectric materials 760 and to contacts on die 740 as well as to electrode 750. Although not visible in this cross-section, additional conductors formed in vias to substrate 745 are formed on opposing sides of electrode 750 (left and right sides as viewed) to serve as anchors for suspension springs. Overlying the conductive material vias in FIG. 14 is patterned conductive line 770 (a first level of conductors). Representatively, the vias may be formed by a drilling process followed by, but not limited to, a semi-additive process. Conductive material in the vias and patterned conductive lines may be formed using an electroless seed layer followed by a dry film resist (DFR) patterning and plating. The DFR may then be stripped followed by a flash etch to remove any electroless seed layer.

FIG. 14 still further shows electrode 775 of, in one embodiment, the conductive material of the first level of conductors and patterned (the suspended electrode(s)) on dielectric layer 760 over electrode 750. Electrode 775 is illustrated with openings 776. In one embodiment, patterning to produce such openings includes patterning a sacrificial material (e.g., DFR) on dielectric layer 760 to block electroless deposition and subsequent plating of a conductive material where such openings are desired.

In addition to electrode 775, in one embodiment, the patterning and plating of conductive material includes a semi-additive process of forming suspension springs to previously formed conductive anchors. FIG. 14 shows a portion of suspension spring 777A and suspension spring 777B connected to second electrode 775.

FIG. 15 shows the structure of FIG. 14 following the introduction and patterning of a sacrificial material on the structure. Sacrificial material 780 of, for example, a DFR, is patterned to expose electrode 775.

FIG. 16 shows the structure of FIG. 15 following removal of dielectric material (a portion of dielectric layer 760) below electrode 775 such that electrode 775 is free to move in at least a z-direction (e.g., move toward dielectric layer 755 as viewed). In one embodiment, openings 776 in electrode 775 allow isotropic plasma undercutting of the dielectric material below the electrode. Following undercutting, sacrificial material 780 is removed.

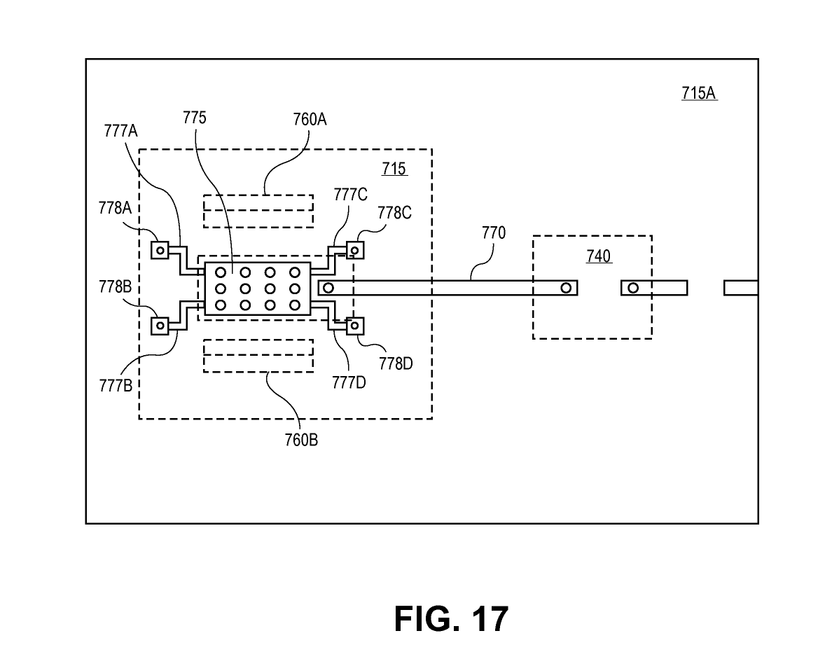

FIG. 17 shows a top view of the structure of FIG. 16. From this view, second electrode 775 is illustrated over dielectric layer 755. Also illustrated are suspension springs 777A, 777B, 777C and 777D connected to electrode 775 and to anchors 778A, 778B, 778C and 778D, respectively.

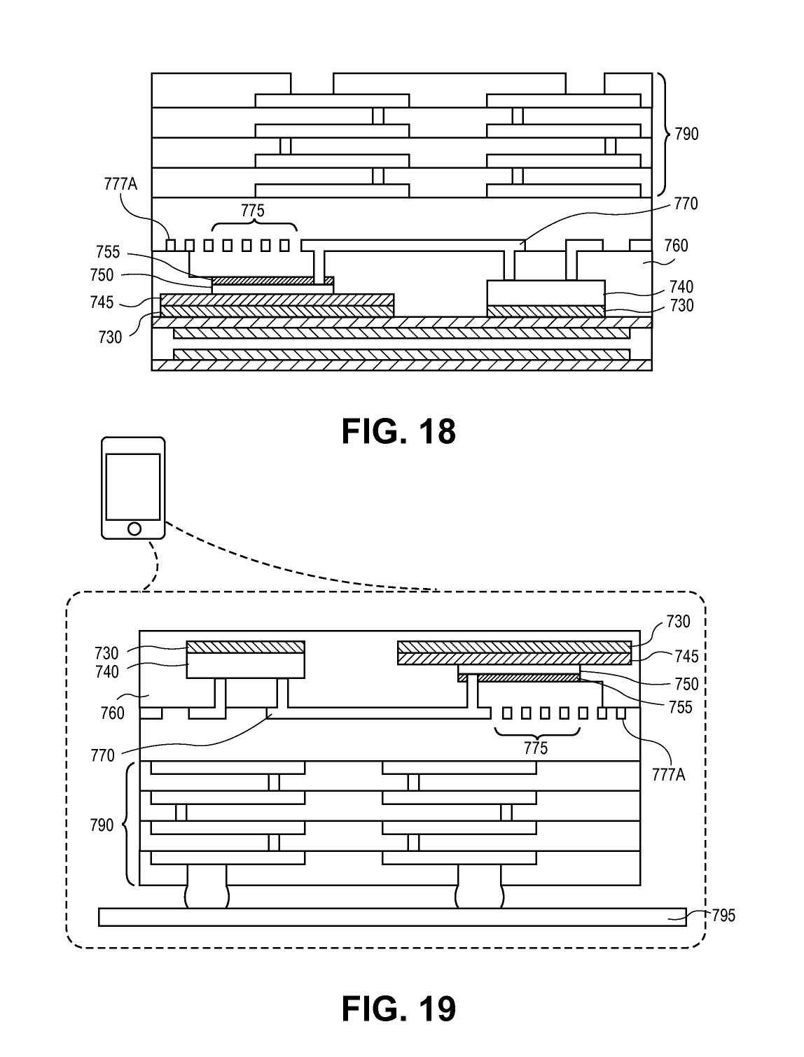

Following the formation of the device (capacitor device) in FIG. 16, formation of a build-up carrier may continue by the introduction of additional levels of conductive material separated by dielectric layers (films). A typical BBUL package may have four to six levels of conductive material (conductive traces or lines) including signal lines, a power line and a ground line. The power and ground lines are connected to the capacitor assembly through conductive vias. FIG. 18 shows the structure of FIG. 16 after the introduction of four additional conductive lines 790 on the structure. An ultimate conductive level is patterned with contacts that are suitable, for example, for a surface mount packaging implementation.

Once the ultimate conductive level of the build-up carrier is patterned, the structure may be removed from sacrificial substrate 310. At that point, a free standing microelectronic device including at least one capacitor assembly is formed in the build-up carrier. If die 740 is a TSV die, additional processes may be performed to access a back side of the die (e.g., a process to remove the adhesive covering the back side). FIG. 19 shows the structure of FIG. 18 following the separation of the package assembly from sacrificial substrate 710 and copper foils 715A and 720A. In FIG. 19, the structure is inverted and connected to printed circuit board 795. Representatively, the package assembly and board are assembled for use in hand-held device 799, such as a smartphone or tablet.

In the above description of forming a build-up carrier, the formation of one capacitor structure was described at approximately a first level of the carrier (a first conductive level or layer). It is appreciated that more than one capacitor structure can be formed at one or more levels or one or more capacitors may be formed at another level or layer or one capacitor could be formed at one level while another is formed at another level. In another embodiment, rather than build the capacitor as part of building the package or carrier, a capacitor such as one or more of any of the capacitors described with reference to FIGS. 1-9 may be constructed separately and then transferred (e.g., monolithically transferred) on or in to a package or carrier. One way to transfer to a build-up carrier is, after introducing a dielectric layer (film) in a volume where such capacitor is desired, form an opening in the dielectric layer (using photolithographic and etch techniques); place the capacitor in the opening; and connect the capacitor to a die or other device using, for example, semi-additive processing techniques.

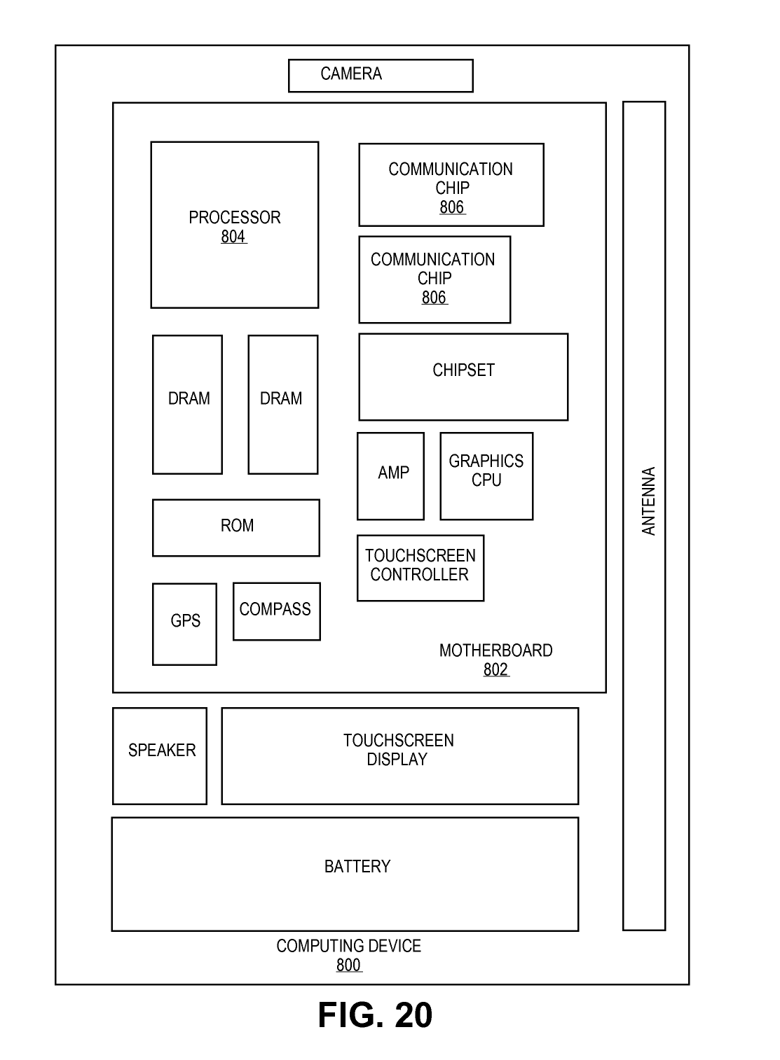

FIG. 20 illustrates a computing device 800 in accordance with one implementation. The computing device 800 houses board 802. Board 802 may include a number of components, including but not limited to processor 804 and at least one communication chip 806. Processor 804 is physically and electrically connected to board 802. In some implementations the at least one communication chip 806 is also physically and electrically connected to board 802. In further implementations, communication chip 806 is part of processor 804.

Depending on its applications, computing device 800 may include other components that may or may not be physically and electrically connected to board 802. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

Communication chip 806 enables wireless communications for the transfer of data to and from computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3 G, 4 G, 5 G, and beyond. Computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

Processor 804 of computing device 800 includes an integrated circuit die packaged within processor 804. In some implementations, the package formed in accordance with embodiment described above utilizes BBUL technology with one or more capacitors positioned in or on a build-up carrier of the package. The term “processor” may refer to any device or portion of a device that processes electronic data from registers and/or memory to transform that electronic data into other electronic data that may be stored in registers and/or memory.

Communication chip 806 also includes an integrated circuit die packaged within communication chip 806. In accordance with another implementation, a package including a communication chip incorporates one or more capacitors such as described above.

In further implementations, another component housed within computing device 800 may contain a microelectronic package that may incorporate one or more capacitors in or on the package.

In various implementations, computing device 800 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, computing device 800 may be any other electronic device that processes data.

### Examples

The following examples pertain to embodiments.

Example 1 is an apparatus including a die; a carrier coupled to the die, the carrier including contact points for connection to another device or assembly; at least one capacitor positioned in or on the carrier, the at least one capacitor including a first electrode, a second electrode including an electrode surface suspended over an electrode surface of the first electrode and a dielectric material disposed between the first electrode and the second electrode; and a magnet positioned in or on the carrier such that a magnetic field produced by the magnet at least partially actuates the second electrode toward the first electrode.

In Example 2, the magnet of the apparatus of Example 1 includes a first pole and an opposite second pole, wherein the first pole and the second pole are disposed on opposite sides of the capacitor.

In Example 3, the apparatus of Example 1 further includes a current source coupled to the second electrode and configured to produce a current in a direction orthogonal to the magnetic field.

In Example 4, the apparatus of Example 1 further includes at least one spring coupled to the second electrode at a first side and at least one spring coupled to the second electrode at an opposite second side.

In Example 5, the at least one spring of the apparatus of Example 4 is coupled to a first side of the second electrode has a spring rate that is less than the at least one spring coupled to a second side of the second electrode.

In Example 6, the at least one spring of the apparatus of Example 4 includes a first pair of springs coupled to a first side of the second electrode and a second pair of springs coupled to a second side of the second electrode, wherein the first pair of springs and the second pair of springs include one of a different spring rate of the respective pair and a different spring rate than the opposing pair.

In Example 7, the apparatus of Example 1 further includes at least one spring coupled to the second electrode at a first side and at least one spring coupled to the second electrode at an opposite second side, wherein the first electrode and the second electrode each include a plurality of plates that are set off from adjacent plates in a planar array.

In Example 8, the first electrode and the second electrode of the apparatus of Example 1, each includes a plurality of plates that are set off from adjacent plates in a planar array, and the apparatus further includes at least one spring coupled to each opposing side of each plate of the second electrode.

In Example 9, the apparatus of any of Examples 1-8 is used in an RF circuit, such as used as a filter component in an RF circuit.

Example 10 is a method including disposing a die, a first electrode of a capacitor and a magnet on a sacrificial substrate; forming a dielectric layer on a surface of the first electrode; patterning a conductive material coupled to a contact point of the die and coupled to the first electrode; patterning a second electrode on the dielectric layer; and removing the sacrificial substrate.

In Example 11, the method of Example 10 further includes prior to patterning the conductive material, introducing a first dielectric film on the dielectric layer and the die such that the conductive material is disposed on the dielectric film; and after patterning the conductive material and the second electrode, introducing a second dielectric film on the patterned conductive material and the second electrode.

In Example 12, the method of Example 11 further includes, prior to introducing the second dielectric film, removing a portion of the dielectric film on the dielectric layer.

In Example 13, the magnet described in the method of Example 10 includes a first pole and an opposite second pole, and the first pole and the second pole are disposed on opposite sides of the first electrode.

In Example 14, the die and the first electrode described in the method of Example 10 are disposed on a substrate, the method further including patterning at least one spring connection between the substrate and each of opposite sides of the second electrode.

In Example 15, the at least one spring connection described in the method of Example 14 includes a first pair of spring connections coupled to a first side of the second electrode and a second pair of spring connections coupled to a second side of the second electrode, wherein the first pair of spring connections and the second pair of spring connections comprise one of a different spring rate of the respective pair and a different spring rate than the opposing pair.

In Example 16, patterning the second electrode described in Example 14 includes patterning a plurality of plates that are set off from adjacent plates in a planar array.

In Example 17, patterning at least one spring connection between the substrate and each of opposite sides of the second electrode described in Example 16 includes patterning at least one spring connection to each opposing side of each of the plurality of plates.

In Example 18, forming a dielectric layer described in Example 10 includes chemical vapor depositing.

Example 19 is a method including exposing a suspended first electrode of a capacitor in a package to a magnetic field; driving a current in a first direction through the first electrode; and establishing a voltage difference between the first electrode and a second electrode.

In Example 20, a direction of the magnetic field relative to the direction of the current in the method of Example 19 establishes a Lorentz force on the first electrode.

In Example 21, the method of Example 19 further includes applying a voltage between the first electrode and the second electrode.

In the description above, for the purposes of explanation, numerous specific details have been set forth in order to provide a thorough understanding of the embodiments. It will be apparent however, to one skilled in the art, that one or more other embodiments may be practiced without some of these specific details. The particular embodiments described are not provided to limit the invention but to illustrate it. The scope of the invention is not to be determined by the specific examples provided above but only by the claims below. In other instances, well-known structures, devices, and operations have been shown in block diagram form or without detail in order to avoid obscuring the understanding of the description. Where considered appropriate, reference numerals or terminal portions of reference numerals have been repeated among the figures to indicate corresponding or analogous elements, which may optionally have similar characteristics.

It should also be appreciated that reference throughout this specification to “one embodiment”, “an embodiment”, “one or more embodiments”, or “different embodiments”, for example, means that a particular feature may be included in the practice of the invention. Similarly, it should be appreciated that in the description various features are sometimes grouped together in a single embodiment, figure, or description thereof for the purpose of streamlining the disclosure and aiding in the understanding of various inventive aspects. This method of disclosure, however, is not to be interpreted as reflecting an intention that the invention requires more features than are expressly recited in each claim. Rather, as the following claims reflect, inventive aspects may lie in less than all features of a single disclosed embodiment. Thus, the claims following the Detailed Description are hereby expressly incorporated into this Detailed Description, with each claim standing on its own as a separate embodiment of the invention.

What is claimed is:

1. An apparatus comprising:
a die;
a carrier coupled to the die, the carrier comprising contact points for connection to another device or assembly; and
at least one capacitor positioned in or on the carrier, the at least one capacitor comprising a first electrode, a second electrode comprising an electrode surface suspended over an electrode surface of the first electrode and a dielectric material disposed between the first electrode and the second electrode; and
a magnet positioned in or on the carrier such that a magnetic field produced by the magnet at least partially actuates the second electrode toward the first electrode.

2. The apparatus of claim 1, wherein the magnet comprises a first pole and an opposite second pole, wherein the first pole and the second pole are disposed on opposite sides of the capacitor.

3. The apparatus of claim 1, further comprising a current source coupled to the second electrode and configured to produce a current in a direction orthogonal to the magnetic field.

4. The apparatus of claim 1, further comprising at least one spring coupled to the second electrode at a first side and at least one spring coupled to the second electrode at an opposite second side.

5. The apparatus of claim 4, wherein the at least one spring coupled to a first side of the second electrode has a spring rate that is less than the at least one spring coupled to a second side of the second electrode.

6. The apparatus of claim 4, wherein the at least one spring comprises a first pair of springs coupled to a first side of the second electrode and a second pair of springs coupled to a second side of the second electrode, wherein the first pair of springs and the second pair of springs comprise one of a different spring rate of the respective pair and a different spring rate than the opposing pair.

7. The apparatus of claim 1, further comprising at least one spring coupled to the second electrode at a first side and at least one spring coupled to the second electrode at an opposite second side, wherein the first electrode and the second electrode each comprise a plurality of plates that are set off from adjacent plates in a planar array.

8. The apparatus of claim 1, wherein the first electrode and the second electrode each comprise a plurality of plates that are set off from adjacent plates in a planar array, the apparatus further comprising at least one spring coupled to each opposing side of each plate of the second electrode.

9. A method comprising:
disposing a die, a first electrode of a capacitor and a magnet on a sacrificial substrate;
forming a dielectric layer on a surface of the first electrode;
patterning a conductive material coupled to a contact point of the die and coupled to the first electrode;
patterning a second electrode on the dielectric layer; and
removing the sacrificial substrate.

10. The method of claim 9, further comprising:
prior to patterning the conductive material, introducing a first dielectric film on the dielectric layer and the die such that the conductive material is disposed on the dielectric film; and
after patterning the conductive material and the second electrode, introducing a second dielectric film on the patterned conductive material and the second electrode.

11. The method of claim 10, further comprising:
prior to introducing the second dielectric film, removing a portion of the dielectric film on the dielectric layer.

12. The method of claim 9, wherein the magnet comprises a first pole and an opposite second pole, wherein the first pole and the second pole are disposed on opposite sides of the first electrode.

13. The method of claim 9, wherein the die and the first electrode are disposed on a substrate, the method further comprising:
patterning at least one spring connection between the substrate and each of opposite sides of the second electrode.

14. The method of claim 13, wherein the at least one spring connection comprises a first pair of spring connections coupled to a first side of the second electrode and a second pair of spring connections coupled to a second side of the second electrode, wherein the first pair of spring connections and the second pair of spring connections comprise one of a different spring rate of the respective pair and a different spring rate than the opposing pair.

15. The method of claim 13, wherein patterning the second electrode comprises patterning a a plurality of plates that are set off from adjacent plates in a planar array.

16. The method of claim 15, wherein patterning at least one spring connection between the substrate and each of opposite sides of the second electrode comprises patterning at least one spring connection to each opposing side of each of the plurality of plates.

17. The method of claim 9, wherein forming a dielectric layer comprises chemical vapor depositing.

18. A method comprising:
exposing a suspended first electrode of a capacitor in a package to a magnetic field;
driving a current in a first direction through the first electrode; and
establishing a voltage difference between the first electrode and a second electrode.

19. The method of claim 18, wherein a direction of the magnetic field relative to the direction of the current establishes a Lorentz force on the first electrode.

20. The method of claim 18, further comprising applying a voltage between the first electrode and the second electrode.
